(19) United States
(12) Patent Application Publication
(10) Pub. No.: US 2014/0167059 A1
(43) Pub. Date: Jun. 19, 2014

(54) PEC ETCHING OF (20-2-1) SEMIPOLAR GALLIUM NITRIDE FOR EXTERNAL EFFICIENCY ENHANCEMENT IN LIGHT EMITTING DIODE APPLICATIONS

(71) Applicant: The Regents of the University of California, Oakland, CA (US)

(72) Inventors: Chung-Ta Hsu, Santa Barbara, CA (US); Chia-Yen Huang, Goleta, CA (US); Yuji Zhao, Goleta, CA (US); Shih-Chieh Haung, Goleta, CA (US); Daniel F. Feezell, Albuquerque, NM (US); Steven P. DenBaars, Goleta, CA (US); Shuji Nakamura, Santa Barbara, CA (US); James S. Speck, Goleta, CA (US)

(21) Appl. No.: 14/014,904

(22) Filed: Aug. 30, 2013

Related U.S. Application Data
(60) Provisional application No. 61/695,124, filed on Aug. 30, 2012.

(51) Int. Cl. H01L 33/00; H01L 33/32

(52) U.S. Cl. CPC H01L 33/0075; H01L 33/32
USPC 257/76; 438/46

(57) ABSTRACT

A method of performing a photoelectrochemical (PEC) etch on an exposed surface of a semipolar {20-2-1} III-nitride semiconductor, for improving light extraction from and for enhancing external efficiency of one or more active layers formed on or above the semipolar {20-2-1} III-nitride semiconductor.

### CROSS REFERENCE TO RELATED APPLICATIONS

This application claims the benefit under 35 U.S.C Section 119(e) of the following co-pending and commonly-assigned patent application:

U.S. Provisional Patent Application Ser. No. 61/695,124, filed on Aug. 30, 2012, by Chung-Ta Hsu, Chia-Yen Huang, Yuji Zhao, Shih-Chieh Haung, Daniel F. Feezell, Steven P. DenBaars, Shuji Nakamura, and James S. Speck, and entitled “PEC ETCHING OF {20-2-1} SEMIPOLAR GALLIUM NITRIDE FOR SEMIPOLAR FOR EXTERNAL EFFICIENCY ENHANCEMENT IN LIGHT EMITTING DIODE APPLICATIONS,” attorney's docket number 30794.466-US-P1 (2013-034-1);

which application is incorporated by reference herein.

This application is related to the following co-pending and commonly-assigned patent applications:

U.S. Utility patent application Ser. No. 13/283,259, filed on Oct. 27, 2011, by Yuji Zhao, Junichi Sonoda, Chih-Chien Pan, Shinichi Tanaka, Steven P. DenBaars, and Shuji Nakamura, entitled “HIGH POWER, HIGH EFFICIENCY AND LOW EFFICIENCY DROOP III-NITRIDE LIGHT-EMITTING DIODES ON SEMIPOLAR {20-2-1} SUBSTRATES,” attorneys' docket number 30794.403-US-U1 (2011-258-2), which application claims the benefit under 35 U.S.C. Section 119(e) of co-pending and commonly-assigned U.S. Provisional Patent Application Ser. No. 61/407,357, filed on Oct. 27, 2010, by Yuji Zhao, Junichi Sonoda, Chih-Chien Pan, Shinichi Tanaka, Steven P. DenBaars, and Shuji Nakamura, entitled “HIGH POWER, HIGH EFFICIENCY AND LOW EFFICIENCY DROOP III-NITRIDE LIGHT-EMITTING DIODES ON SEMIPOLAR {20-2-1} SUBSTRATES,” attorneys' docket number 30794.403-US-P1 (2011-258-1);

U.S. Utility patent application Ser. No. 13/459,963, filed on Apr. 30, 2012, by Yuji Zhao, Shinichi Tanaka, Chia-Yen Huang, Daniel F. Feezell, James S. Speck, Steven P. DenBaars, and Shuji Nakamura, entitled “HIGH INDIUM UPTAKE AND HIGH POLARIZATION RATIO FOR GROUP-III NITRIDE OPTOELECTRONIC DEVICES FABRICATED ON A SEMIPOLAR {20-2-1} PLANE OF A GALLIUM NITRIDE SUBSTRATE,” attorneys' docket number 30794.411-US-U1 (2011-580-2), which application claims the benefit under 35 U.S.C. Section 119(e) of co-pending and commonly-assigned U.S. Provisional Patent Application Ser. No. 61/480,968, filed on Apr. 29, 2011, by Yuji Zhao, Shinichi Tanaka, Chia-Yen Huang, Daniel F. Feezell, James S. Speck, Steven P. DenBaars, and Shuji Nakamura, entitled “HIGH INDIUM UPTAKES AND HIGH POLARIZATION RATIO ON GALLIUM NITRIDE SEMIPOLAR {20-2-1} SUBSTRATES FOR III-NITRIDE OPTOELECTRONIC DEVICES,” attorneys' docket number 30794.411-US-P1 (2011-580-1);

all of which applications are incorporated by reference herein.

### BACKGROUND OF THE INVENTION

1. Field of the Invention

The present invention relates generally to photoelectrochemical (PEC) etching of {20-2-1} semipolar GaN for external efficiency enhancement of light emitting diode (LED) applications.

2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

Existing III-nitride light emitting diodes (LEDs) and laser diodes (LDs) are typically grown on {0001} polar, {10-10} and {11-20} nonpolar, or {11-22}, {20-21} and {10-1-1} semipolar planes. LEDs and LDs grown on polar and semipolar planes suffer from polarization related electric fields in the quantum wells that degrade device performance. While {10-10} and {11-20} nonpolar devices are free from polarization related effects, incorporation of high Indium concentrations in {10-10} nonpolar devices and high quality crystal growth of {11-20} nonpolar devices have been shown to be difficult to achieve.

High-power green III-nitride-based LEDs have been demonstrated on the {11-22} and {20-21} semipolar planes and low-threshold green III-nitride-based LDs also have been shown on the {20-21} semipolar plane. [1-3] Devices grown on the {20-2-1} semipolar plane of III-nitrides have also attracted considerable attention. [4-5]

Specifically, devices grown on a {20-2-1} semipolar plane of Gallium Nitride (GaN), which is a semipolar plane comprised of a miscut from the m-plane in the c-direction, have attracted much attention because of their potential of high performance due to the reduced polarization-related electric fields in the quantum wells as compared to conventional semipolar planes (i.e., {11-22}, {10-1-1}, etc.). Moreover, an LED grown on the {20-2-1} semipolar plane of GaN should provide a lower QCSE (quantum confined Stark effect) induced, injection current dependent, blue shift in its output wavelength, as well as increased oscillator strength, leading to higher material gain, etc., as compared to a polar c-plane GaN LEDs and other nonpolar or semipolar GaN devices. In addition, GaN LEDs grown along the {20-2-1} semipolar plane, are likely to show better performance at long wavelengths, since semi-polar planes are believed to incorporate Indium more easily. Finally, a GaN LED grown on the {20-2-1} semipolar plane should exhibit reduced efficiency droop, which is a phenomenon that describes the decrease in the external quantum efficiency (EQE) with increasing injection current.

Nonetheless, there is a need in the art for improved methods of enhancing the external efficiency of devices using {20-2-1} semipolar III-nitride semiconductors. The present invention satisfies this need.

### SUMMARY OF THE INVENTION

To overcome the limitations in the prior art described above, and to overcome other limitations that will become apparent upon reading and understanding the present specification, the present invention discloses a method of photoelectrochemical (PEC) etching of {20-2-1} semipolar GaN for surface roughening of light emitting devices to improve light extraction and enhance external efficiency. Using the present invention results in improved semipolar GaN based LED performance. The surface morphology of {20-2-1} semipolar GaN showed significant roughening with a much higher root mean square (RMS) roughness, scanned by atomic force microscopy (AFM), as compared to other semipolar planes under the same etching conditions. This roughened surface morphology resulting from PEC etching can be an economical and rapid technique for enhancing the extraction efficiency of semipolar GaN LEDs and LDs.

### BRIEF DESCRIPTION OF THE DRAWINGS

Referring now to the drawings in which like reference numbers represent corresponding parts throughout:

FIG. 1 illustrates an apparatus used for PEC etching, according to one embodiment of the present invention.

FIG. 2 is a flowchart that illustrates a method for wet etching the semiconductor sample so that chemical etching only proceeds in areas illuminated by light.

FIG. 3 is a graph showing Etch Rate (Å/s) and Roughness (nm) as a function of KOH concentration (M).

FIG. 4 shows a sequence of scanning electron microscope (SEM) images of (20-2-1) semipolar GaN after PEC etching in 30 minute periods with various molarities of KOH, as labeled in the upper left corner of each of the SEM images.

FIG. 5 shows a sequence of atomic force microscopy (AFM) images of (20-2-1) semipolar GaN after PEC etching in 30 minute periods with various molarities of KOH, as labeled in the upper left corner of each of the AFM images.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Etching Apparatus

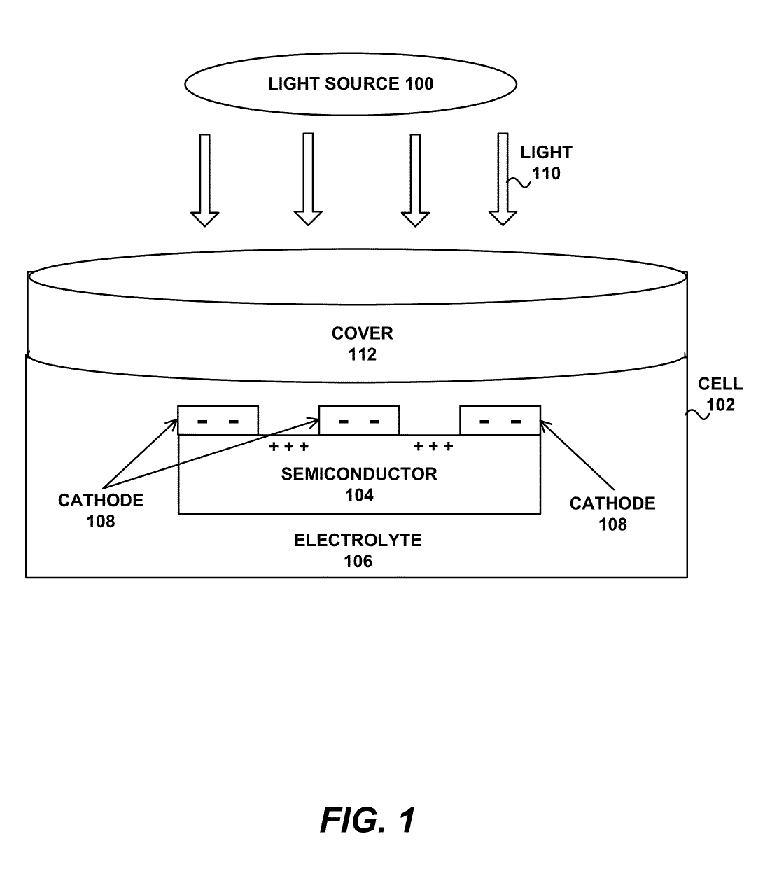

FIG. 1 is a schematic that illustrates the apparatus used in the PEC etching of the present invention, wherein the PEC etching is a photo-assisted wet etch process that can be used to etch III-nitride semiconductors including GaN and its alloys. The apparatus is comprised of a light source 100 and an electrochemical cell 102, where a semiconductor 104 immersed in an electrolyte 106 acts as an anode and the semiconductor 104 has metal in contact therewith or patterned directly thereon that act as cathodes 108. Light 110 from the light source 100 generates electron-hole pairs in the semiconductor 104, wherein electrons (−) are extracted through the cathodes 108, while holes (+) participate in oxidation reactions at the semiconductor 104 surface, causing the semiconductor 104 surface to be dissolved in the electrolyte 106. A cover 112, which is transparent to the light 110 from the light source 100, is used to seal the electrochemical cell 102.

In one embodiment, the light source 100 comprises a 1000 Watt broadband Xenon lamp with a spot size of 2 inches in diameter. The III-nitride semiconductor 104 is a GaN sample comprised of epitaxial (20-2-1) semipolar GaN layers grown by metalorganic chemical vapor deposition (MOCVD) on a (20-2-1) semipolar GaN substrate provided by Mitsubishi Chemical Corporation. The GaN sample 104 is processed using standard lithographic techniques, followed by electron-beam deposition of 100 nm of Ti and 300 nm of Pt on the GaN sample 104 for use as both cathodes 108 and an etch mask. An additional (and optional) etch mask may also be used on the GaN sample 104 (not shown). The surface that is etched comprises a {20-2-1} semipolar surface of either the epitaxial GaN layers or the GaN substrate. The electrolyte solution 106 is KOH, which is selected for its high chemical reactivity, leading to a rapid etch rate. The cover 112 is comprised of sapphire with 90% light transmission, which seals the top of the cell 102 to prevent evaporation of the solution 106.

### PEC Etching Process

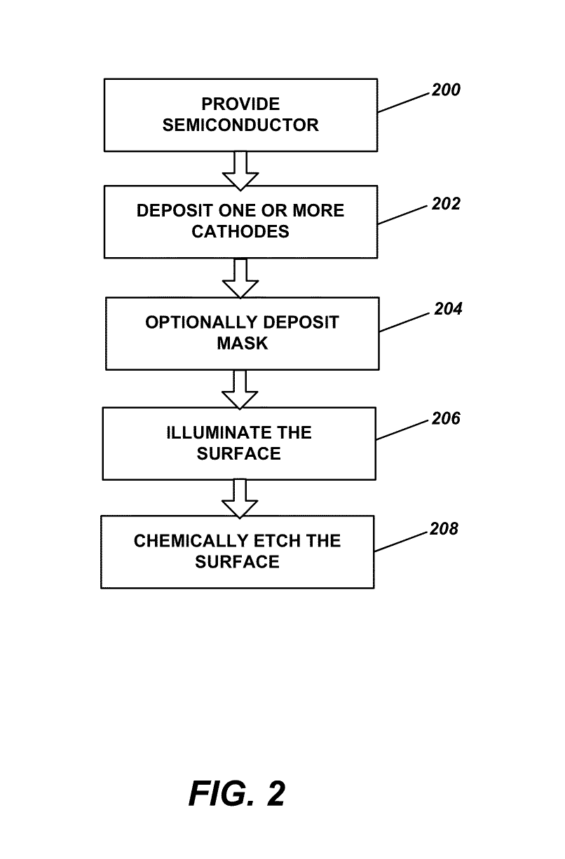

FIG. 2 is a flowchart that illustrates a method for wet etching the III-nitride semiconductor using the apparatus of FIG. 1, so that chemical etching only proceeds in areas illuminated by light. Specifically, the flowchart that illustrates a method of fabricating a light emitting device, comprising performing a photoelectrochemical (PEC) etch on an exposed surface of a {20-2-1} semipolar III-nitride semiconductor, to shape, pattern or roughen the exposed surface, for improving light extraction from and for enhancing external efficiency of, a device formed on or above the {20-2-1} semipolar III-nitride semiconductor.

In one embodiment, the method includes the following steps.

Block 200 represents the step of providing the {20-2-1} semipolar III-nitride semiconductor 104.

Block 202 represents depositing one or more cathodes 108 on an exposed surface of the semiconductor 104.

Block 204 represents the optional step of depositing an additional insulating and opaque etch mask on the exposed surface of the semiconductor 104.

Block 206 represents placing the semiconductor 104 in the cell 102, so that it is immersed in the electrolyte solution 106 and electrically coupled to a current source via the cathode 108, and then illuminating those portions of the exposed surface of the semiconductor 104 that are not covered by the cathodes 108 or the optional mask using the light source 100. An external bias from the current source may be applied between the cathode 108 and a reference electrode in the electrolyte solution 106.

Block 208 represents the etching of the illuminated semiconductor 104, using the electrolyte solution 106, to form a shaped, patterned or roughened surface. The etched surface comprises a {20-2-1} semipolar surface of the semiconductor 104.

Note that Block 208 may include the step of controlling the PEC etch so that the etching of the surface is more photo driven and less chemically driven. For example, the controlling step may comprise balancing an incident light intensity with electrolyte concentration for the PEC etch. The controlling step may include determining an etched profile of the surface by an incident light direction for the PEC etch, wherein the etching only proceeds in areas illuminated by the incident light for the PEC etch. Further, the balancing step may include selecting a balance between the incident light intensity with the electrolyte concentration for the PEC etch to achieve a more rapid and deeper etching.

The end result of the etching process is a {20-2-1} semipolar III-nitride semiconductor 104 having at least one surface that is shaped, patterned or roughened, resulting in conical features, for improving the light extraction and for enhancing the external efficiency of one or more active layers of a light emitting device formed on or above the {20-2-1} semipolar III-nitride semiconductor.

### Experimental Results

In molarity series measurements for the {20-2-1} semipolar III-nitride semiconductor, namely, PEC etching of (20-2-1) semipolar GaN, both etching rate and roughness were investigated using various molarities or concentrations of KOH.

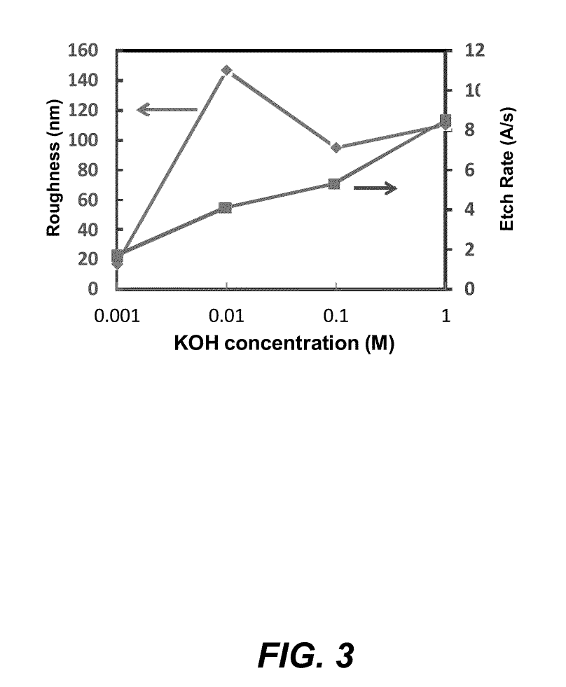

FIG. 3 is a graph showing an Etch Rate in angstroms per second (Å/s) and a root mean square (RMS) Roughness in nanometers (nm) as a function of KOH concentration (M). The solvent concentrations were etched for 30 minute periods.

A KOH concentration ranging from about 0.001 M to about 1 M was selected as an electrolyte for the photoelectrochemical etch to obtain an etch rate for the exposed surface ranging from about 2 Å/s to about 8 Å/s. Specifically, the selections resulted in the following:
the etch rate for the exposed surface is about 2 Å/s for the selected KOH concentration of about 0.001 M,
the etch rate for the exposed surface is about 4 Å/s for the selected KOH concentration of about 0.01 M,
the etch rate for the exposed surface is about 5 Å/s for the selected KOH concentration of about 0.1 M, and
the etch rate for the exposed surface is about 8 Å/s for the selected KOH concentration of about 1 M.

A KOH concentration ranging from about 0.001 M to about 1 M was selected as an electrolyte for the photoelectrochemical etch to obtain a root mean square (RMS) roughness for the exposed surface ranging from about 20 nm to about 150 nm. Specifically, the selections resulted in the following:
the RMS roughness for the exposed surface is about 20 nm for the selected KOH concentration of about 0.001 M,
the RMS roughness for the exposed surface is about 150 nm for the selected KOH concentration of about 0.01 M,
the RMS roughness for the exposed surface is about 100 nm for the selected KOH concentration of about 0.1 M, and
the RMS roughness for the exposed surface is about 120 nm for the selected KOH concentration of about 1 M.

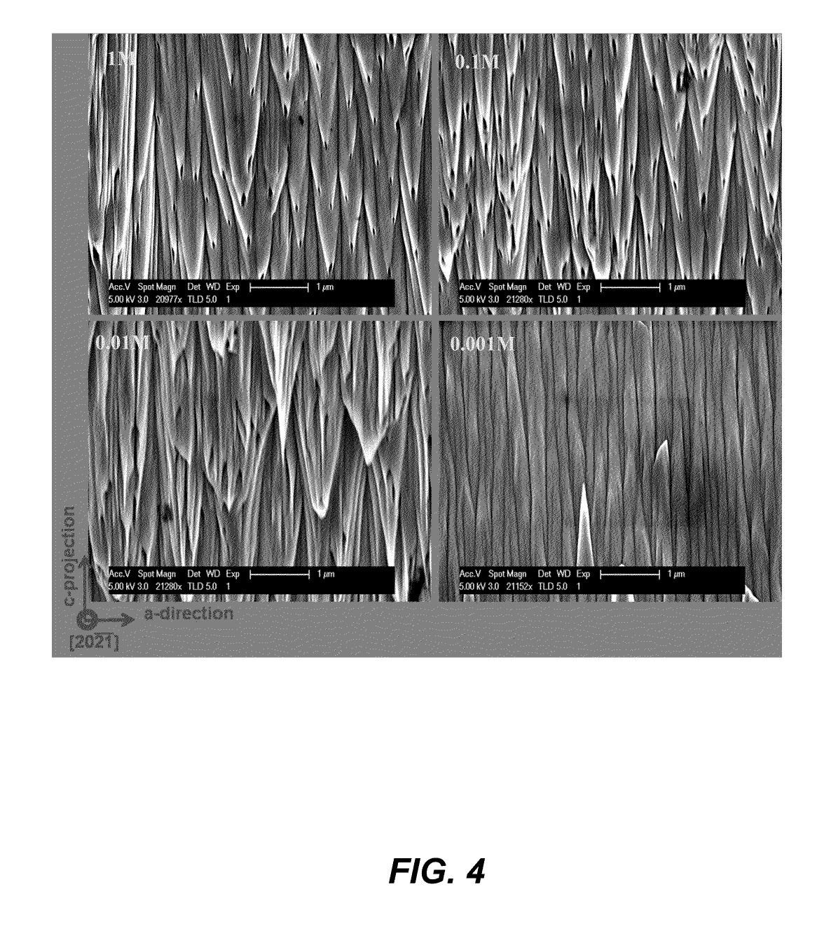

FIG. 4 shows a sequence of scanning electron microscope (SEM) images of (20-2-1) semipolar GaN after PEC etching for 30 minute periods with the various molarities of KOH, as labeled in the upper left corner of each of the SEM images.

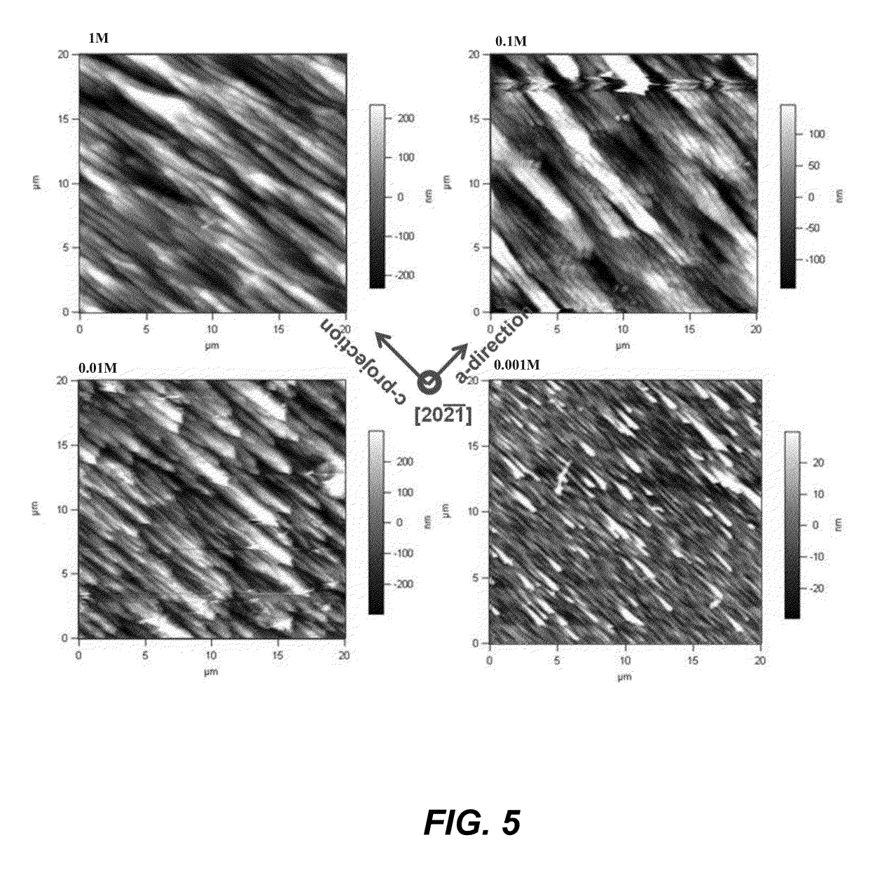

FIG. 5 shows a sequence of atomic force microscopy (AFM) images of (20-2-1) semipolar GaN after PEC etching for 30 minute periods with the various molarities of KOH, as labeled above the upper left corner of each of the AFM images.

### Nomenclature

The terms “Group-III nitride” or “III-nitride” or “nitride” as used herein refer to any composition or material related to (B, Al, Ga, In)N semiconductors having the formula B_{w}AlₓGa_{y}In_{z}N where 0≦w≦1, 0≦x≦1, 0≦y≦1, 0≦z≦1, and w+x+y+z=1. These terms as used herein are intended to be broadly construed to include respective nitrides of the single species, B, Al, Ga, and In, as well as binary, ternary and quaternary compositions of such Group III metal species. Accordingly, these terms include, but are not limited to, the compounds of AlN, GaN, InN, AlGaN, AlInN, InGaN, and AlGaInN. When two or more of the (B, Al, Ga, In)N component species are present, all possible compositions, including stoichiometric proportions as well as off-stoichiometric proportions (with respect to the relative mole fractions present of each of the (B, Al, Ga, In)N component species that are present in the composition), can be employed within the broad scope of this invention. Further, compositions and materials within the scope of the invention may further include quantities of dopants and/or other impurity materials and/or other inclusional materials.

This invention also covers the selection of particular crystal orientations, directions, terminations and polarities of Group-III nitrides. When identifying crystal orientations, directions, terminations and polarities using Miller indices, the use of braces, { }, denotes a set of symmetry-equivalent planes, which are represented by the use of parentheses, ( ). The use of brackets, [ ], denotes a direction, while the use of brackets, < >, denotes a set of symmetry-equivalent directions.

Many Group-III nitride devices are grown along a polar orientation, namely a c-plane {0001} of the crystal, although this results in an undesirable quantum-confined Stark effect (QCSE), due to the existence of strong piezoelectric and spontaneous polarizations. One approach to decreasing polarization effects in Group-III nitride devices is to grow the devices along nonpolar or semipolar orientations of the crystal.

The term “nonpolar” includes the {11-20} planes, known collectively as a-planes, and the {10-10} planes, known collectively as m-planes. Such planes contain equal numbers of Group-III and Nitrogen atoms per plane and are charge-neutral. Subsequent nonpolar layers are equivalent to one another, so the bulk crystal will not be polarized along the growth direction.

The term “semipolar” can be used to refer to any plane that cannot be classified as c-plane, a-plane, or m-plane. In crystallographic terms, a semipolar plane would be any plane that has at least two nonzero h, i, or k Miller indices and a nonzero 1 Miller index. Subsequent semipolar layers are equivalent to one another, so the crystal will have reduced polarization along the growth direction.

### REFERENCES

The following references are incorporated by reference herein:

[1] S. Yamamoto, Y. Zhao, C. C. Pan, R. B. Chung, K. Fujito, J. Sonoda, S. P. DenBaars, and S. Nakamura, Appl. Phys. Express 3 122102 (2010).

[2] Y. Enya, Y. Yoshizumi, T. Kyono, K. Akita, M. Ueno, M. Adachi, T. Sumitomo, S. Tokuyama, T. Ikegami, K. Katayama, and T. Nakamura, Appl. Phys. Express 2 082101 (2009).

[3] Y. Yoshizumi, M. Adachi, Y. Enya, T. Kyono, S. Tokuyama, T. Sumitomo, K. Akita, T. Ikegami, M. Ueno, K. Katayama, and T. Nakamura, Appl. Phys. Express 2 092101 (2009).

[4] Y. Zhao, S. Tanaka, C. C. Pan, K. Fujito, D. Feezell, J. S. Speck, S. P. DenBaars, and S. Nakamura, Appl. Phys. Express 4 082104 (2011).

[5] C. Y. Huang, M. T. Hardy, K. Fujito, D. F. Feezell, J. S. Speck, S. P. DenBaars, and S. Nakamura, Appl. Phys. Lett. 99, 241115 (2011).

[6] Y. Kawaguchi, C. Y. Huang, Y. R. Wu, Q. Yan, C. C. Pan, Y. Zhao, S. Tanaka, K. Fujito, D. F. Feezell, C. G. V. de Walle, S. P. DenBaars and S. Nakamura, Appl. Phys. Lett. 100, 231110 (2012).

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method of fabricating a light emitting device, comprising:
performing a photoelectrochemical (PEC) etch on an exposed surface of a semipolar {20-2-1} III-nitride semiconductor, for improving light extraction from and for enhancing external efficiency of, one or more active layers formed on or above the semipolar {20-2-1} III-nitride semiconductor.

2. The method of claim 1, wherein the photoelectrochemical etch is performed to shape, pattern or roughen the exposed surface of the semipolar {20-2-1} III-nitride semiconductor.

3. The method of claim 1, further comprising selecting a KOH concentration ranging from about 0.001 M to about 1 M as an electrolyte for the photoelectrochemical etch to obtain an etch rate for the exposed surface ranging from about 2 Å/s to about 8 Å/s.

4. The method of claim 3, wherein the etch rate for the exposed surface is about 2 Å/s for the selected KOH concentration of about 0.001 M.

5. The method of claim 3, wherein the etch rate for the exposed surface is about 4 Å/s for the selected KOH concentration of about 0.01 M.

6. The method of claim 3, wherein the etch rate for the exposed surface is about 5 Å/s for the selected KOH concentration of about 0.1 M.

7. The method of claim 3, wherein the etch rate for the exposed surface is about 8 Å/s for the selected KOH concentration of about 1 M.

8. The method of claim 1, further comprising selecting a KOH concentration ranging from about 0.001 M to about 1 M as an electrolyte for the photoelectrochemical etch to obtain a root mean square (RMS) roughness for the exposed surface ranging from about 20 nm to about 150 nm.

9. The method of claim 8, wherein the RMS roughness for the exposed surface is about 20 nm for the selected KOH concentration of about 0.001 M.

10. The method of claim 8, wherein the RMS roughness for the exposed surface is about 150 nm for the selected KOH concentration of about 0.01 M.

11. The method of claim 8, wherein the RMS roughness for the exposed surface is about 100 nm for the selected KOH concentration of about 0.1 M.

12. The method of claim 8, wherein the RMS roughness for the exposed surface is about 120 nm for the selected KOH concentration of about 1 M.

13. The method of claim 1, wherein the semipolar {20-2-1} III-nitride semiconductor comprises one or more epitaxial Gallium Nitride (GaN) layers grown on a (20-2-1) semipolar GaN substrate.

14. A semipolar {20-2-1} III-nitride semiconductor etched by the method of claim 1.

15. A light emitting apparatus, comprising:
a semipolar {20-2-1} III-nitride semiconductor having an exposed surface that is a photoelectrochemical (PEC) etched surface; and
one or more active layers formed on or above the semipolar {20-2-1} III-nitride semiconductor;
wherein the photoelectrochemical etched surface improves light extraction from the active layers and enhances external efficiency of the active layers.

16. The apparatus of claim 15, wherein the semipolar {20-2-1} III-nitride semiconductor comprises one or more epitaxial Gallium Nitride (GaN) layers grown on a (20-2-1) semipolar GaN substrate.
